(19) United States
(12) Patent Application Publication
(10) Pub. No.: US 2004/0012549 A1
(43) Pub. Date: Jan. 22, 2004

(54) Electroluminescent display device and manufacturing method of the same

(75) Inventor: Ryuji Nishikawa, Gifu-shi (JP)

Correspondence Address: MORRISON & FOERSTER LLP, 1650 TYSONS BOULEVARD, SUITE 300, MCLEAN, VA, 22102, US

(73) Assignee: Sanyo Electric Co., Ltd., Moriguchi-City (JP)

(21) Appl. No.: 10/430,383

(22) Filed: May 7, 2003

(30) Foreign Application Priority Data
May 9, 2002 (JP) 2002-134354

(51) Int. Cl. G09G 3/30

(52) U.S. Cl. 345/76

(57) ABSTRACT

An electroluminescent display device has a device glass substrate and a sealing glass substrate that are attached together with a sealing resin. The device glass substrate has a pixel region provided with an organic EL element, and a horizontal driving circuit and a vertical driving circuit, both of which supply driving signals for driving the organic EL element. The sealing glass substrate is provided with a light shield layer for preventing incident light from entering the horizontal driving circuit and the vertical driving circuit. This makes edges of an organic EL panel clear, thereby improving a display contrast.

### BACKGROUND OF THE INVENTION

1 Field of the Invention

This invention relates to an electroluminescent display device and a manufacturing method thereof, particularly to an electroluminescent display device with an improved display qualities.

2. Description of the Related Art

In recent years, electroluminescent (hereafter, referred to as EL) display devices with an EL element have been receiving an attention as a display device replacing a CRT and an LCD.

FIG. 6 is a schematic view showing a structure of a conventional organic EL panel. A pixel region and a peripheral driving circuit region are formed on a device glass substrate 1. The pixel region includes a plurality of pixels and each of the pixels has an organic EL element, an organic EL element driving TFT (thin film transistor), TFTa, and a pixel selecting TFT (not shown). For example, the organic EL element driving TFT, TFTa, has an active layer made of a polysilicon layer. A light shield layer 3 made of Cr (chromium) is disposed below TFTa with an insulating film 2 interposed therebetween.

This light shield layer 3 is placed off the position exactly below the active layer of TFTa. The reason is as follows. In the manufacturing process of this display device, the active layer of TFTa is initially made of an amorphous silicon. This amorphous silicon is then crystallized by excimer laser irradiation. At this process step, if the light shield layer 3 made of Cr is located exactly below the active layer of TFTa, thermal conductivity becomes high. This makes it difficult to control grain sizes of the active layer, thereby degrading characteristics of TFTa.

A peripheral driving circuit disposed in a periphery of the pixel region includes many TFTs, TFTb, as well as related wiring (not shown). The light shield layer 3 made of Cr is not formed exactly below TFTb with the same reason as described above.

The device glass substrate 1 is attached to a sealing glass substrate 5 with a sealing resin 4 made of an epoxy resin interposed therebetween.

As described above, since the light shield layer 3 is not formed exactly below TFTbs in the peripheral driving circuit, light incident from the sealing glass substrate 5 penetrates to the device glass substrate 1. Therefore, edges of the organic EL panel become blurred to an observer and a display contrast is degraded.

### SUMMARY OF THE INVENTION

The invention provides an electroluminescent display device that includes a first substrate, an electroluminescent element disposed on the first substrate, a peripheral driving circuit disposed on a peripheral portion of the first substrate and supplying a driving signal for the electroluminescent element, a second substrate attached to the first substrate, and a light shield layer covering the peripheral driving circuit.

The invention also provides an electroluminescent display device that includes a first substrate, an electroluminescent element disposed on the first substrate, a peripheral driving circuit disposed on a peripheral portion of the first substrate and supplying a driving signal for the electroluminescent element, a second substrate attached to the first substrate, and means for preventing light coming from the second substrate and entering the peripheral driving circuit from passing through the first substrate.

The invention further provides a manufacturing method of an electroluminescent display device. The method includes providing a first substrate having thereon an electroluminescent element and a peripheral driving circuit for supplying a driving signal for driving the electroluminescent element. The peripheral driving circuit is disposed on a peripheral portion of the first substrate. The method also includes forming a light shield layer on a second substrate, forming a photoresist layer on the light shield layer at a peripheral region of the second substrate, and removing a portion of the light shield layer by etching using the photoresist layer as a mask. The method further includes forming a pocket region on the second substrate by etching the second substrate using the photoresist layer and the remaining light shield layer as a mask, removing the photoresist layer, forming a desiccant layer in the pocket region, and attaching the second substrate to the first substrate.

### BRIEF DESCRIPTION OF THE DRAWINGS

FIG. 1 is a plan view of a device glass substrate according to an embodiment of the invention.

FIG. 2 is an equivalent circuit diagram of a pixel formed on a pixel region shown in FIG. 1

FIGS. 3A and 3B are cross-sectional views of an organic EL panel according to the embodiment.

FIG. 4 is a partial cross-sectional view of the pixel region and a peripheral driving circuit region shown in FIG. 1.

FIGS. 5A-5F show manufacturing steps of a sealing glass substrate of the embodiment.

FIG. 6 is a cross-sectional view of a conventional organic EL panel.

### DETAILED DESCRIPTION OF THE INVENTION

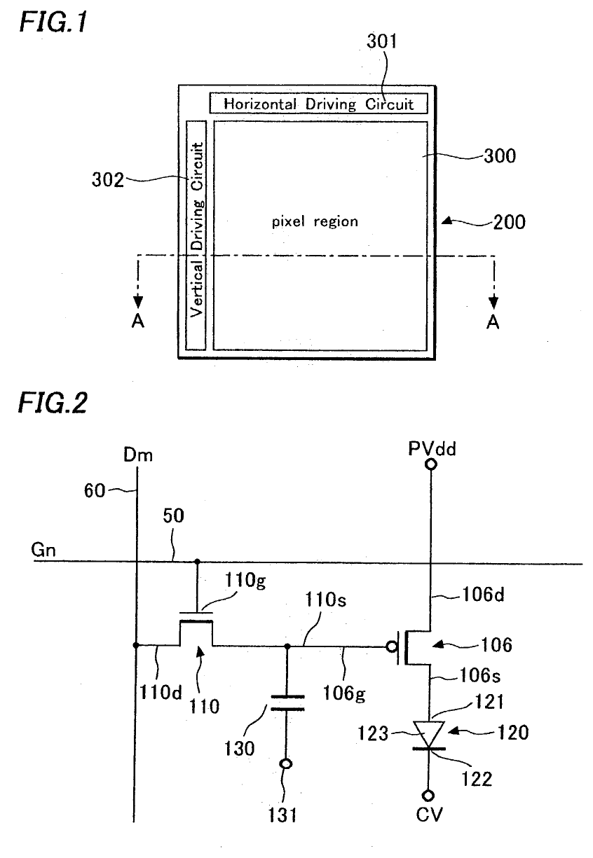

Next, there will be described an embodiment of the invention with reference to FIGS. 1-5F. First, a structure of a device glass substrate 200 of this embodiment will be described with reference to FIGS. 1 and 2.

As shown in FIG. 1, there are disposed on the device glass substrate 200 a pixel region 300, and a horizontal driving circuit 301 and a vertical driving circuit 302 as a peripheral driving circuit of the pixel region. The vertical driving circuit 302 supplies a gate signal Gn (a horizontal scanning signal) to each pixel of the pixel region 300. The horizontal driving circuit 301 supplies a drain signal (a video signal Dm) to each pixel of the pixel region 300 in accordance with the horizontal scanning signal.

FIG. 2 is an equivalent circuit diagram of one of the pixels placed in the pixel region 300. A gate signal line 50 for supplying the gate signal Gn and a drain signal line 60 for supplying the drain signal, i.e. the video signal Dm intersect each other.

There are disposed in the vicinity of the intersection of both signal lines an organic EL element 120, a TFT 106 for driving the organic EL element 120 and a TFT 110 for selecting a pixel.

A positive source voltage PVdd is supplied to a drain 106d of the organic EL element driving TFT 106. A source 106s is connected to an anode 121 of the organic EL element 120.

A gate 110g of the pixel selecting TFT 110 is connected to the gate signal line 50, receiving the gate signal Gn, and a drain 110d of the pixel selecting TFT 110 is connected to the drain signal line 60, receiving the video signal Dm. A source 110s of the TFT 110 is connected to a gate 106g of the organic EL element driving TFT 106. The gate signal Gn is outputted from a vertical driving circuit 302. The video signal Dm is outputted from a horizontal driving circuit 301.

The organic EL element 120 includes the anode 121, a cathode 122 and an emissive layer 123 disposed between the anode 121 and the cathode 122. The cathode 122 is supplied with a negative source voltage CV.

A storage capacitor 130 is connected to the gate 106g of the TFT 106. That is, one of the electrodes of the storage capacitor 130 is connected to the gate 106g, and the other electrode is connected to a storage capacitor electrode 131. The storage capacitor 130 is provided to hold the video signal of the display pixel for one field period by keeping the charge corresponding to the video signal Dm.

The operation of the EL display device having the above structure is described as follows. The pixel selecting TFT 110 turns on when the gate signal Gn becomes a high level for one horizontal period. Then, the video signal Dm is applied from the drain signal line 60 to the gate 106g of the organic EL element driving TFT 106 through the TFT 110. The conductance of the TFT 106 changes in response to the video signal Dm supplied to the gate 106g, and a driving current corresponding to the changed conductance is supplied to the organic EL element 120 through the TFT 106. Then, the organic EL element 120 emits light.

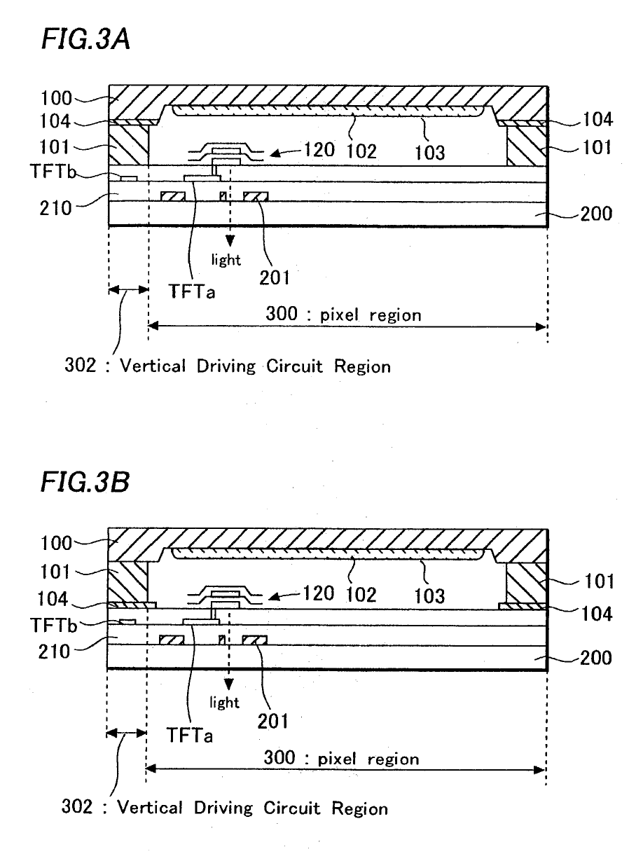

Next, there will be described a structure of an organic EL panel that includes the device glass substrate 200 and the related structures described above as well as a sealing glass substrate 100 that covers the device glass substrate 200, with reference to FIGS. 3A and 3B. FIG. 3A is a cross-sectional view corresponding to line A-A of FIG. 1.

The device glass substrate 200 and the sealing glass substrate 100 are attached together at corresponding edges with a sealing resin 101 made of a resin material that works as an adhesive, such as an epoxy resin. This prevents moisture infiltration from the outside. The device glass substrate 200 and the sealing glass substrate 100 may have the same thickness of about 0.7 mm.

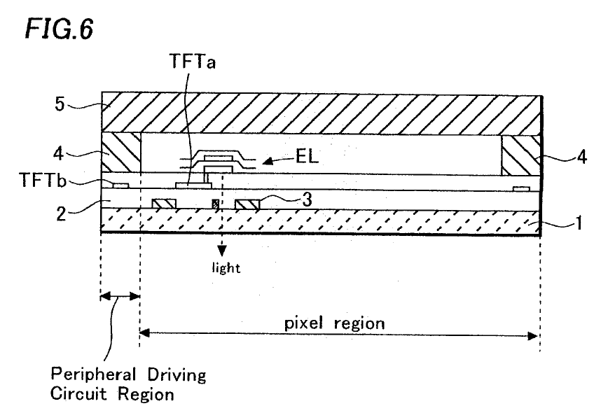

A plurality of pixels is disposed in a matrix in the pixel region 300 of the device glass substrate 200. Each of the pixels includes the organic EL element 120, the organic EL element driving TFT, TFTa, and the pixel selecting TFT, as described above. For example, TFTa has the active layer made of a polysilicon layer. A light shield layer 201 made of Cr (chromium) is disposed below TFTa with an insulating film 210 interposed therebetween. The light shield layer 201 is placed off the position exactly below the active layer of TFTa, as is the case with the display panel of FIG. 6.

A concave portion (hereafter, referred to as a pocket region 102) is formed on an inside surface of the sealing glass substrate 100 facing the device glass substrate 200 by etching. A depth of the pocket region 102 is preferably 0.1 to 0.3 mm, and a desiccant layer 103 is formed on a bottom of the pocket region 102. The desiccant layer 103 is formed, for example, by coating resin dissolved with powdered calcium oxide or barium oxide and an adhesive on the bottom of the pocket region 102 and hardening the resin by UV irradiation or heating. Forming of the pocket region 102 is for securing a gap between the desiccant layer 103 and the organic EL element 120 to prevent the breaking of the EL element due to contacting with the desiccant layer 103.

Furthermore, a light shield layer 104 having a laminated structure of a chromium oxide layer and a chromium layer is formed on a convex portion in the periphery of the pocket region 102. The light shield layer 104 is disposed to cover the vertical driving circuit 302. Although not shown in FIG. 3, the light shield layer 104 is extended to cover the horizontal driving circuit 301.

In the above-described structure, since the light shield layer 104 is disposed in the region over the vertical driving circuit 302 and the horizontal driving circuit 301, light incident from the sealing glass substrate 100 can be shielded. Thus, edges of the organic EL panel are clear to improve a display contrast.

In this embodiment, the forming of the light shield layer 104 is not restricted to the top surface of the convex portion in the periphery of the pocket region 102, but can be in any position as long as the position is over the vertical driving circuit 302 and the horizontal driving circuit 301. For example, the light shield layer 104 may be formed on an outside surface of the device glass substrate 200 instead of on the surface of the sealing glass substrate 100. Specifically, the light shield layer 104 may be placed on the surface of an insulating layer that covers the TFTs, TFTa, TFTb, formed on the device glass substrate 200, as shown in FIG. 3B. In addition, the pocket region 102 may not be formed in the sealing glass substrate 100.

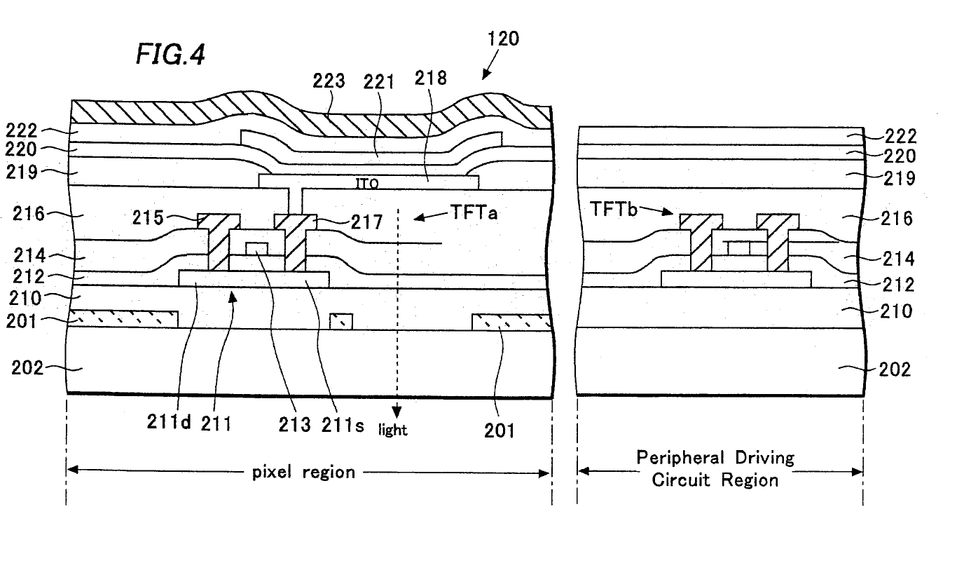

FIG. 4 is a partial cross-sectional view of the pixel region 300 and the peripheral driving circuit region, for example, the region of the vertical driving circuit 302. The organic EL element 120 and TFTa are shown in the pixel region 300, and TFTb is shown in the peripheral driving circuit region. In the pixel region, TFTa is formed over an insulating substrate 202 made of a silica glass or a non-alkali glass with an insulating film 210 interposed therebetween. TFTa includes an active layer 21 1 formed by poly-crystallizing an amorphous silicon film by laser irradiation, a gate insulating film 212, and a gate electrode 213 made of a metal having a high melting point such as Cr or Mo (molybdenum). The active layer 211 is provided with a channel, and a source 21 Is and a drain 211d on each side of the channel.

The light shield layer 201 is formed on an insulating substrate 202 below TFTa.

The light shield layer 201 is formed in a region except the region exactly below the active layer 211.

An interlayer insulating film 214 laminated with an SiO₂ film, an SiNx film and an SiO₂ film sequentially is formed on the whole surfaces of the gate insulating film 212 and the active layer 211. There is disposed a driving source line 215 (a drain electrode) connected to a driving source PVdd by filling a contact hole provided correspondingly to a drain 211d with a metal such as Al. Furthermore, a first planarization insulating film 216 for planarizing the surface, which is made of, for example, an organic resin is formed on the whole surface. A contact hole is formed in a position corresponding to a source 211s in the planarization insulating film 216. There is formed on the first planarization insulating film 216 a transparent electrode made of ITO (Indium Tin Oxide) and contacting to a source electrode 217 through the contact hole, i.e., an anode layer 218 of the organic EL element 120. The anode layer 218 is formed in each of the pixels, being isolated as an island.

A second planarization insulating film 219 is formed in a periphery of the anode layer 218. The second planarization insulating film 219 on the anode layer 218 is removed. The organic EL element is formed by laminating the anode layer 218, a hole transport layer 220, an emissive layer 221, an electron transport layer 222 and a cathode layer 223 in this order.

A TFT, TFTb, is formed in the peripheral driving circuit region. A structure of TFTb is the same as that of TFTa in the pixel region except that the light shield layer 201 is not provided in its lower layer. The light shield layer 104 is provided on the sealing glass substrate 100 as described above.

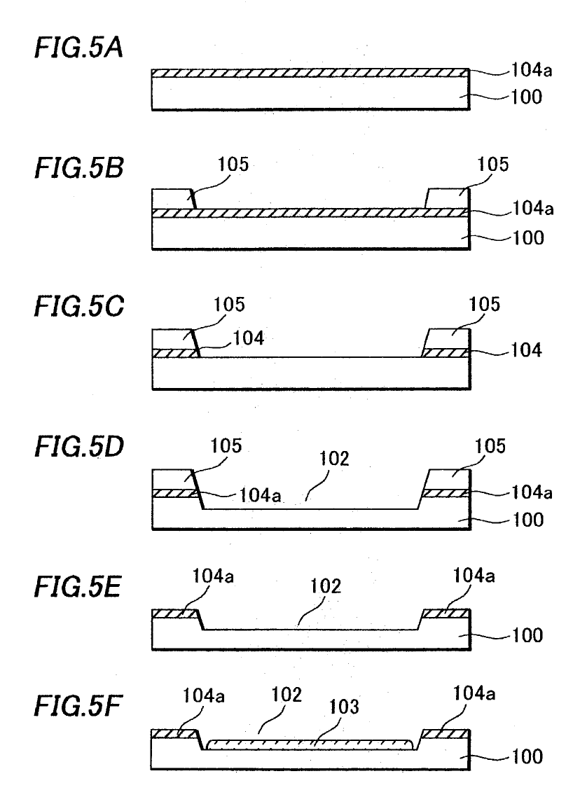

Next, a manufacturing method of the sealing glass substrate 100 provided with the light shield layer 104 will be described with reference to FIGS. 5A-5F.

First, as shown in FIG. 5A, chromium oxide and chromium layers 104a is formed on the sealing glass substrate 100 by sputtering. Then, as shown in FIG. 5B, a photoresist layer 105 is formed on the chromium oxide and chromium layers 104a. The photoresist layer 105 is formed in a region corresponding to the peripheral driving circuit.

Next, as shown in FIG. 5C, the chromium oxide and chromium layers 104a is removed by etching using the photoresist layer 105 as a mask. The light shield layer 104 remains under the photoresist layer 105.

As shown in FIG. 5D, the surface of the sealing glass substrate 100 is removed by etching with hydrofluoric acid (HF) by using the photoresist layer 105 and the light shield layer 104 as a mask. The etching continues, for example, for two hours and the sealing glass substrate 100 is etched by approximately 0.3 mm. Here, the light shield layer 104 functions as a mask for etching with the photoresist layer 105. Thus, the pocket region 102 is formed.

Then, as shown in FIG. 5E, the photoresist layer 105 is removed. The light shield layer 104 is not removed and remains as it is. As shown in FIG. 5F, the desiccant layer 103 is formed on the bottom of the pocket region 102. The sealing glass substrate 100 thus produced is attached to the device glass substrate 200 with the sealing resin 101. Thus, the organic EL panel shown in FIGS. 3A and 3B is completed.

In this manufacturing method, the chromium oxide and chromium layers are used for forming the pocket region 102 and as the light shield layer 104 in the completed display device. Therefore, an additional step for forming the light shield layer is not required when the display panel has the pocket region.

What is claimed is:

1. An electroluminescent display device comprising:
a first substrate;
an electroluminescent element disposed on the first substrate;
a peripheral driving circuit disposed on a peripheral portion of the first substrate and supplying a driving signal for the electroluminescent element;
a second substrate attached to the first substrate; and
a light shield layer covering the peripheral driving circuit.

2. The electroluminescent display device of claim 1, wherein the light shield layer is disposed on a peripheral portion of the second substrate.

3. The electroluminescent display device of claim 2, wherein the second substrate includes a pocket portion having a desiccant therein, and the light shield layer is disposed around the pocket portion.

4. The electroluminescent display device of claim 1, wherein the light shield layer is disposed on a peripheral portion of the first substrate.

5. The electroluminescent display device of claim 1, wherein the light shield layer comprises a chromium layer and a chromium oxide layer.

6. The electroluminescent display device of claim 1, wherein each of the first and second substrates is made of a glass.

7. An electroluminescent display device comprising:
a first substrate;
an electroluminescent element disposed on the first substrate;
a peripheral driving circuit disposed on a peripheral portion of the first substrate and supplying a driving signal for the electroluminescent element;
a second substrate attached to the first substrate; and
means for preventing light coming from the second substrate and entering the peripheral driving circuit from passing through the first substrate.

8. A manufacturing method of an electroluminescent display device, comprising:
providing a first substrate having thereon an electroluminescent element and a peripheral driving circuit for supplying a driving signal for driving the electroluminescent element, the peripheral driving circuit being disposed on a peripheral portion of the first substrate;
forming a light shield layer on a second substrate;
forming a photoresist layer on the light shield layer at a peripheral region of the second substrate;
removing a portion of the light shield layer by etching using the photoresist layer as a mask;
forming a pocket region on the second substrate by etching the second substrate using the photoresist layer and the remaining light shield layer as a mask;
removing the photoresist layer;
forming a desiccant layer in the pocket region; and
attaching the second substrate to the first substrate.

9. The manufacturing method of the electroluminescent display device of claim 8, wherein the forming of the light shield layer comprises laminating a chromium layer and a chromium oxide layer on the second substrate.
